(19) United States
(12) Patent Application Publication
(10) Pub. No.: US 2026/0190503 A1
(43) Pub. Date: Jul. 2, 2026

(54) ELECTROSTATIC DISCHARGE PROTECTION STRUCTURE INCLUDING A TRIGGER CIRCUIT DISCONNECT SWITCH AND METHODS

(71) Applicant: GlobalFoundries U.S. Inc., Malta, NY (US)

(72) Inventors: Alain F. Loiseau, Williston, VT (US); Annabelle G. Cunningham, Winooski, VT (US); Sagar Premnath Karalkar, North Chelmsford, MA (US); Nandha Kumar Subramani, Dresden (DE); Ivan B. Dimov, Sofia (BG); Jing Wan, Milton, VT (US)

(21) Appl. No.: 19/008,073

(22) Filed: Jan. 2, 2025

(51) Int. Cl. H10D 89/60

(52) U.S. Cl. CPC H10D 89/811

(57) ABSTRACT

Disclosed is an electrostatic discharge (ESD) protection structure for a circuit component connected to a first pad by an interconnect. The structure includes: a trigger circuit; a trigger circuit disconnect switch connected between the interconnect and trigger circuit; and a discharge circuit connected to a trigger voltage output node of the trigger circuit and to the interconnect. The switch enables the interconnect to be disconnected from the trigger circuit during testing of the circuit component (e.g., during wafer level testing to assess gate integrity) and to otherwise be continuously connected to the trigger circuit to facilitate ESD protection. The switch can be a depletion mode high electron mobility transistor (HEMT) with a gate connected to a second pad, which is connected to receive a negative voltage during testing and which is otherwise left floating. Also disclosed are a package chip including the ESD protection structure and associated methods.

### GOVERNMENT LICENSE RIGHTS

This invention was made with government support under Contract Number HQ0727790700 awarded by the Defense Microelectronics Activity (DMEA). The government has certain rights in the invention.

### BACKGROUND

The present disclosure relates to electrostatic discharge (ESD) protection structures and, more particularly, to embodiments of an ESD protection structure and associated methods.

During integrated circuit (IC) chip manufacturing, testing is typically performed at the wafer level (i.e., before the wafer is cut into individual chips the chips and before the chips are packaged for use in electronic devices). Wafer level testing can include, but is not limited, gate integrity testing. Gate integrity testing refers to testing performed to determine whether or not transistors violate maximum leakage current specifications. However, when an ESD protection structure is connected between a first pad and the gate of a transistor in order to protect the transistor in the event of ESD, leakage inherently occurs through the ESD protection structure and, particularly, through a trigger circuit thereof. As a result, it may be difficult to accurately assess the gate integrity of that transistor.

### SUMMARY

Disclosed herein are embodiments of electrostatic discharge (ESD) protection structure. The ESD protection structure can include: a trigger circuit; and a trigger circuit disconnect switch, which is connected between the trigger circuit and an interconnect (which connects a first pad to a circuit component). The ESD protection structure can also include a discharge circuit, which is connected to a trigger voltage output node of the trigger circuit and to the interconnect.

Also disclosed herein are embodiments of a chip package structure. The chip package structure can include an interconnect, which is connected between a first pad and a circuit component. The chip package structure can also include an ESD protection structure. The ESD protection structure can include: a trigger circuit; and a trigger circuit disconnect switch, which is connected to a second pad. The trigger circuit disconnect switch and the trigger circuit can be series-connected between the interconnect and a third pad. The ESD protection structure can also include a discharge circuit, which is connected to a trigger voltage output node of the trigger circuit and further connected between the interconnect and the third pad.

Also disclosed herein are associated method embodiments. For example, a disclosed method can include closing a trigger circuit disconnect switch of an ESD protection structure for a circuit component on a chip. The circuit component can be connected by an interconnect to a first pad. The ESD protection structure can include: a trigger circuit; and a trigger circuit disconnect switch, which is connected to a second pad. The trigger circuit disconnect switch and the trigger circuit can further be connected between the interconnect and a third pad. The ESD protection structure can also include a discharge circuit, which is connected to a trigger voltage output node of the trigger circuit and which is further connected between the interconnect and the third pad. The method can further include, when the trigger circuit disconnect switch is closed such that the trigger circuit is disconnected from the interconnect, testing the circuit component.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1A is a schematic diagram illustrating, generally, embodiments of an ESD protection structure;

FIG. 1B is a schematic diagram illustrating, in greater detail, some embodiments of an ESD protection structure;

FIGS. 2A-2C are schematic diagrams illustrating example trigger circuits, respectively, that could be incorporated into the ESD protection structure of FIG. 1A or 1B;

FIGS. 3A-3C are cross-section diagrams illustrating examples of a high electron mobility transistor (HEMT), a HEMT modified to include a P-type III-V semiconductor layer, and a metal-insulator-semiconductor high electron mobility transistor (MISHEMT), respectively;

FIG. 4 is a flow diagram illustrating disclosed method embodiments; and

FIG. 5 is a schematic diagram illustrating embodiments of a chip package.

### DETAILED DESCRIPTION

As mentioned above, during integrated circuit (IC) chip manufacturing, testing is typically performed at the wafer level (i.e., before the wafer is cut into individual chips the chips and before the chips are packaged for use in electronic devices). Wafer level testing can include, but is not limited, gate integrity testing. Gate integrity testing refers to testing performed to determine whether or not transistors violate maximum leakage current specifications. However, when an ESD protection structure is connected between a first pad and the gate of a transistor in order to protect the transistor in the event of ESD, leakage inherently occurs through the ESD protection structure and, particularly, through a trigger circuit thereof. As a result, it can be difficult to accurately assess gate integrity of the transistor.

In view of the foregoing disclosed herein are embodiments of an electrostatic discharge (ESD) protection structure including a trigger circuit disconnect switch. Specifically, the ESD protection structure can be for a circuit component, which is connected to a first pad by an interconnect. The ESD protection structure can include: a trigger circuit; a trigger circuit disconnect switch connected between the interconnect and trigger circuit; and a discharge circuit connected to a trigger voltage output node of the trigger circuit and to the interconnect. The switch enables the interconnect to be disconnected from the trigger circuit (e.g., during testing of the circuit component, such as during wafer level gate integrity testing), but otherwise connected to the trigger circuit to facilitate ESD protection. In some embodiments, the switch can be a depletion mode high electron mobility transistor (HEMT), which is normally conductive (i.e., normally in an ON state) but which can be made non-conductive (i.e., switched to an OFF state) during circuit component testing by application of a negative voltage to a second pad connected to the HEMT gate. Also disclosed herein embodiments of a packaged chip (also referred to herein as a chip package) including the ESD protection structure with the switch continuously maintained in a closed state. In embodiments where the switch is a HEMT, the second pad can be left floating (i.e., unconnected to any voltage source) so that that the HEMT remains continuously in the ON state. Also disclosed herein are associated methods.

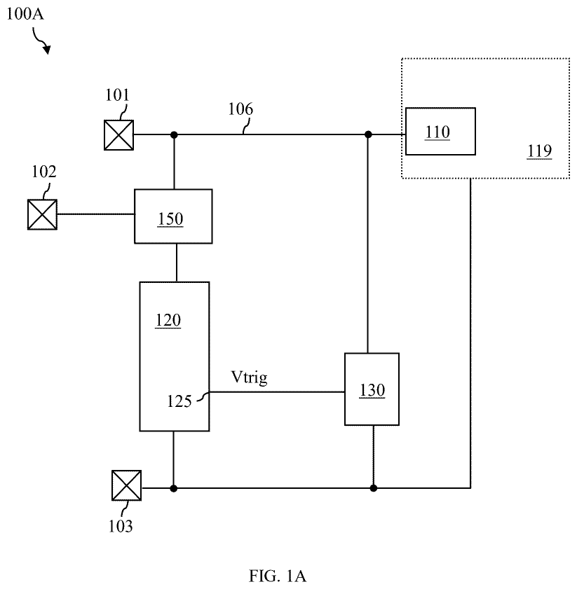

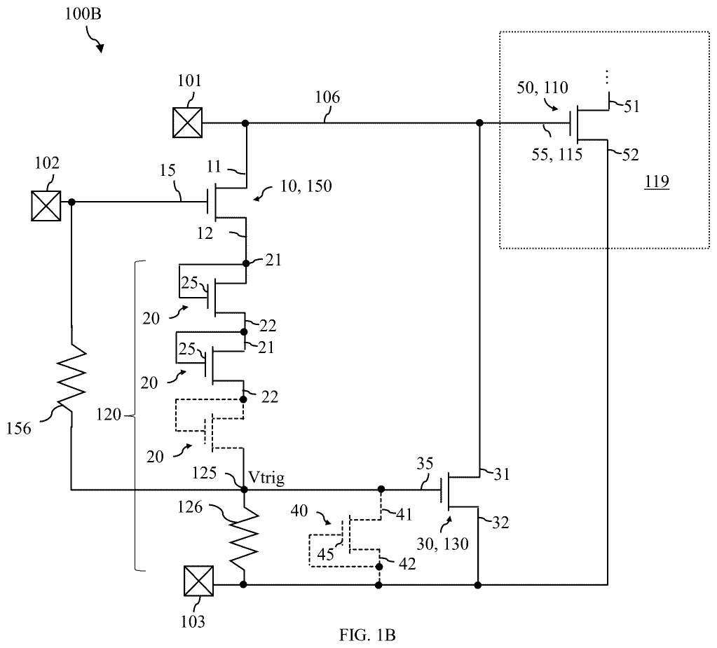

FIG. 1A is a schematic diagram illustrating, generally, embodiments of an ESD protection structure 100A. FIG. 1B is a schematic diagram illustrating, in greater detail, some embodiments of an ESD protection structure 100B. Referring to FIGS. 1A and 1B, ESD protection structure 100A, 100B can be for a component 110 of an operational circuit 119 (e.g., a transceiver front-end or some other operational circuit).

Circuit component 110 can be an ESD-sensitive circuit component. Examples of such ESD-sensitive circuit components are discussed in greater detail below. In any case, circuit component 110 can be electrically connected to a first pad 101 by an interconnect 106. The interconnect between first pad 101 and ESD-sensitive circuit component 110 can include any of back end of the line (BEOL) wire(s) and/or via(s) and/or middle of the line (MOL) contacts. First pad 101 can be, for example, an input pad for receiving a data input signal or a power pad for receiving a power signal. Those skilled in the art will recognize that input and power pads are susceptible to experiencing ESD events. ESD can result in a relatively high positive or negative voltage being transferred via interconnect 106 to the first pad 101 and thereby to the circuit component 110. If the voltage applied by interconnect 106 to circuit component 110 (e.g., during an ESD event or other similar event in which a relatively high positive or negative voltage is received by first pad 101) is above some predetermined damage-inducing voltage level, circuit component 110 and, potentially other circuit components of operational circuit 119 connected thereto can be damaged.

ESD protection structure 100A, 100B can be configured to prevent any voltage over some maximum voltage level (Vmax) from being received by circuit component 110. Specifically, ESD protection structure 100A, 100B can be connected to interconnect 106, ESD protection structure 100A, 100B can include a trigger circuit 120 and a discharge circuit 130. Trigger circuit 120 can include a trigger voltage output node 125. Trigger circuit 120 can further be configured to sense the voltage (Vsen) on first pad 101 and, when Vsen rises above Vmax, generate and output (from trigger voltage output node 125) a trigger voltage (Vtrig) at a sufficient level to turn on discharge circuit 130. Discharge circuit 130 can be electrically connected trigger voltage output node 125 to receive this Vtrig. Discharge circuit 130 can further be connected to interconnect 106 and can be configured to pull-down the voltage level on interconnect 106 in response to Vtrig, thereby preventing damage to circuit component 110. However, as discussed above, a trigger circuit 120 may inherently exhibit some amount of leakage. If wafer level testing of circuit component 110 is desirable, this leakage through trigger circuit 120 may make it difficult to properly assess circuit component 110. For example, as discussed in greater detail below, circuit component 110 could be a transistor with a gate connected to first pad 101 and it may be desirable to test the gate integrity of this transistor But, if trigger circuit 120 is connected directly to interconnect 106 for sensing Vsen, leakage current through trigger circuit 120 would make assessing gate integrity of the transistor difficult.

Therefore, ESD protection structure 100A, 100B further includes a trigger circuit disconnect switch 150 (hereinafter referred to as switch 150), which is electrically connected between interconnect 106 and trigger circuit 120. Switch 150 can enable interconnect 106 to be selectively disconnected from trigger circuit 120 (e.g., during testing of circuit component 110, such as during wafer level gate integrity testing) and to otherwise electrically connect interconnect 106 to trigger circuit 120 to facilitate ESD protection.

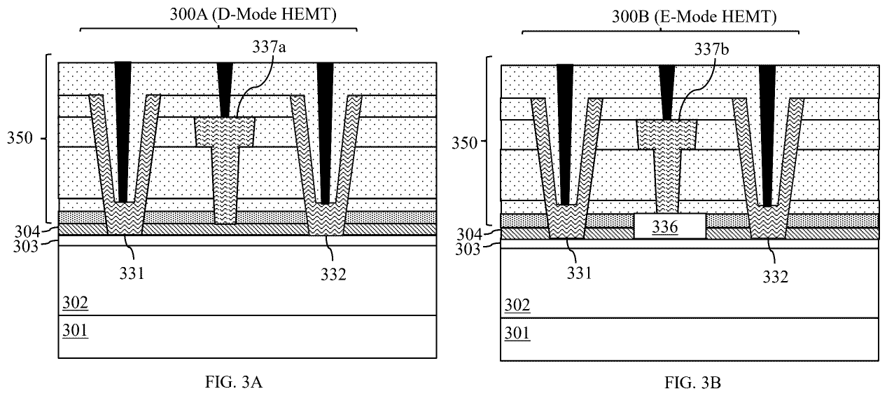

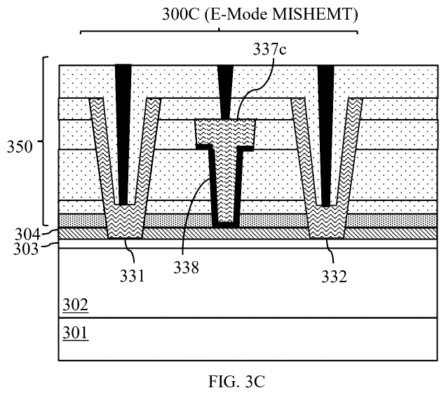

An example of a trigger circuit disconnect switch 150 of ESD protection structure 100A, 100B could include a first transistor 10 (e.g., as illustrated in ESD protection structure 100B of FIG. 1B). First transistor 10 can include: first source/drain regions 11-12, a first channel region between the first source/drain regions 11-12; and a first gate 15 adjacent to the first channel region. First source/drain region 11 can be electrically connected to interconnect 106 between first pad 101 and circuit component 110. First transistor 10 can be a depletion mode transistor. Those skilled in the art will recognize that a depletion mode transistor is a type of field effect transistor that is normally in an ON-state (i.e., a conductive state during which the channel region conducts current through the device) and can be triggered to an OFF-state (i.e., a non-conductive state during which the current is blocked from passing through the channel region). One example of a depletion mode transistor that could be incorporated into the disclosed ESD protection structure 100A or 100B as trigger circuit disconnect switch 150 is a high electron mobility transistor (HEMT), for example, as discussed in greater detail below and illustrated in FIG. 3A. This first gate 15 of this first transistor 10 can be electrically connected (via an interconnect) to a second pad 102 (also referred to herein as a switch control pad) for receiving a switch control voltage. For example, in the case of a depletion mode transistor-type switch, this switch voltage can be a relatively high negative voltage (e.g., −20.0V) to turn open switch 150 (i.e., to switch first transistor 10 from an ON-state to an OFF-state). Absent an applied negative voltage on second pad 102, the depletion mode transistor-type switch 150 will remain closed (i.e., first transistor 10 will remain in an ON-state). It should be understood that the example trigger circuit disconnect switch 150 discussed above is provided for illustration. Alternatively, a different type of switch could be employed, for example, a different type of depletion mode switch or some other now known or currently developed switch. It should be understood that a different type of switch may require different control signal(s) for the state of the switch.

An example of a trigger circuit 120 of ESD protection structure 100A, 100B could include: a resistor 126; and a chain of second transistors 20 connected between switch 150 (e.g., first transistor 10) and resistor 126 (e.g., as illustrated in ESD protection structure 100B of FIG. 1B). In this case, resistor 126 can further be connected between the chain of second transistors 20 and a third pad 103 (also referred to herein as a ground pad for connecting to ground voltage (VSS) (e.g., 0.0 volts (V)). Each second transistor 20 can include: second source/drain regions 21-22, a second channel region between the second source/drain regions 21-22; and a second gate 25 adjacent to the second channel region. In the chain, second transistors 20 are series-connected enhancement mode transistors. Those skilled in the art will recognize that an enhancement mode transistor is a type of field effect transistor (FET) that is normally in an OFF-state (i.e., a non-conductive state during which current flow through the channel region is blocked) and can be triggered to an ON-state (i.e., a conductive state during which current flows through the channel region). One example of an enhancement mode transistor that could be incorporated into ESD protection structure 100A, 100B as a second transistor 20 of trigger circuit 120 is an N-type field effect transistor (NFET). Those skilled in the art will recognize that an NFET typically includes an active device region within a semiconductor layer (e.g., a monocrystalline silicon layer or a monocrystalline layer of some other suitable semiconductor material). Within the active device region, source/drain regions are doped so as to have N-type conductivity at a relatively high conductivity level (e.g., so as to be N+ source/drain regions) and the channel region may be undoped or doped so as to have P-type conductivity at a relatively low conductivity level (e.g., so as to be intrinsic or P-channel regions). A gate adjacent to the channel region can include a gate dielectric layer and a gate conductor layer on the gate dielectric layer. NFETs and various different configurations thereof are well known in the art and, thus, more specific details thereof have been omitted from this specification in order to allow the reader to focus on the salient aspects of the disclosed embodiments.

In any case, second transistors 20 can further be diode-connected transistors. That is, the output from switch 150 (e.g., from first source/drain region 12 is received by second source/drain region 21 of the initial second transistor 20 in the chain and also applied to the second gate 25 of that second transistor 20. If the gate-to-source voltage (Vgs) is above a threshold voltage (Vt), the initial second transistor 20 will switch to an ON-state. The output from second source/drain region 22 of the initial second transistor 20 in the chain is received by second source/drain region 21 of the next second transistor 20 in the chain and also applied to the second gate 25 of that second transistor 20. If the gate-to-source voltage (Vgs) is above a threshold voltage (Vt), the second transistor 20 will switch to an ON-state, and so on. In this example trigger circuit 120, trigger voltage output node 125 can be located at the junction between the chain of second transistors 20 and resistor 126 (i.e., at an interconnect electrically connecting one end of resistor 126 to the second source/drain region 22 of the last second transistor 20 in the chain.

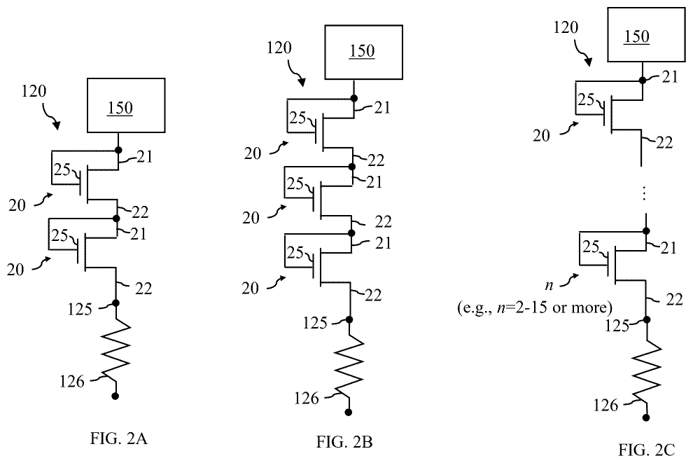

For purposes of illustration, three second transistors 20 are shown in the chain of second transistors in FIG. 1B. However, it should be understood that figures are not intended to be limiting. Alternatively, the chain of second transistors 20 in a trigger circuit 120 can include any number n of second transistors 20, where n=2-15 or even more (e.g., as illustrated in FIG. 2A-2C). It should be understood that the sizes of second transistors 20 and the number n of second transistors 20 can be predetermined during design (e.g., based on simulations) to ensure that, when the voltage level on first pad 101 approaches Vmax, Vtrig will approach a voltage level sufficient to switch on (i.e., trigger) the discharge circuit 130 (e.g., as discussed in greater detail below with regard to the methods).

It should be understood that the example trigger circuit 120 described above and illustrated in FIG. 1B is provided for illustration purposes. Alternatively, any other trigger circuit suitable for sensing the voltage level on first pad 101 and, when the voltage level on first pad 101 approaches Vmax, outputting a Vtrig at a voltage level sufficient to switch on (i.e., trigger) the discharge circuit 130 could be incorporated into ESD protection structure 100A, 100B.

An example of a discharge circuit 130 of ESD protection structure 100A, 100B could include a third transistor 30 (e.g., as illustrated in ESD protection structure 100B of FIG. 1B). Third transistor 30 can include: third source/drain regions 31-32, a third channel region between the third source/drain regions 31-32; and a third gate 35 adjacent to the third channel region. Third source/drain region 31 can be electrically connected to interconnect 106 (between first pad 101 and circuit component 110, downstream of the electrical connection between interconnect 106 and switch 150). Third source/drain region 32 can be electrically connected to third pad 103 (i.e., to the ground pad). Third gate 35 can be electrically connected to trigger voltage output node 125. Third transistor 30 can be an enhancement mode transistor. That is, as discussed above, an enhancement mode transistor is normally in an OFF-state (i.e., a non-conductive state during which current flow through the channel region is blocked) and can be switched to an ON-state (i.e., a conductive state during which current flows through the channel region). In this case, once Vtrig rises to a voltage level sufficient to switch third transistor 30 to the ON-state, current will flow therethrough pulling the voltage level on interconnect 106 down below Vmax before it is applied to circuit component 110. Examples of an enhancement mode transistor that can be incorporated into the disclosed ESD protection structure 100A, 100B as third transistor 30 can include a HEMT modified to include a P-type III-V semiconductor layer (e.g., a P-type gallium nitride layer) in the gate (e.g., as discussed in greater detail below and illustrated in FIG. 3B) or a metal-insulator-semiconductor high electron mobility transistor (MISHEMT) (e.g., as discussed in greater detail below and illustrated in FIG. 3C). Alternatively, third transistor 30 could be an N-type field effect transistor (NFET).

It should be understood that the example discharge circuit 130 described above and illustrated in FIG. 1B is provided for illustration purposes. Alternatively, any other discharge circuit now know or subsequently developed and suitable for pulling down the voltage level of interconnect 106 below Vmax in response to a trigger voltage from a trigger circuit 120 could be incorporated into ESD protection structure 100A, 100B.

Optionally, within ESD protection structure 100A, 100B, second pad 102 (and thereby first gate 15 of first transistor 10 of switch 150) can be electrically connected (e.g., via an additional resistor 156) to trigger voltage output node 125 (and thereby to third gate 35 of third transistor 30 of discharge circuit 130), e.g., as illustrated in ESD protection structure 100B of FIG. 1B. With this configuration, during ESD, when first transistor 10 is in the ON state and Vtrig goes high, high positive Vtrig will further increase the drive current of first transistor 10 to boost performance of trigger circuit 120. Furthermore, during testing of circuit component 110, when a negative voltage is applied to second pad 102 to turn off first transistor 10, that negative voltage will be divided by additional resistor 156 and resistor 126 mentioned above. Thus, a fraction of this negative voltage will also be applied to third gate 35 of third transistor 30 thereby further reducing any leakage current therethrough.

Optionally, ESD protection structure 100A, 100B can further include a fourth transistor 40, which is electrically connected between third gate 35 of third transistor 30 and third pad 103 (e.g., as illustrated in ESD protection structure 100B of FIG. 1B). Fourth transistor 40 can include: fourth source/drain regions 41-42, a fourth channel region between fourth source/drain regions 41-42; and a fourth gate 45 adjacent to the fourth channel region. Fourth source/drain region 41 can be electrically connected to third gate 35. Fourth source/drain region 42 can be electrically connected to third pad 103 (i.e., to the ground pad). Fourth transistor 40 can further be a diode-connected enhancement mode transistor with fourth source/drain region 42 also connected to fourth gate 45. Inclusion of such a fourth transistor 40 can be advantageous during a negative voltage ESD event, as discussed in greater detail below.

An example of circuit component 110 protected by ESD protection structure 100A, 100B could include a fifth transistor 50 (e.g., as illustrated in ESD protection structure 100B of FIG. 1B). Fifth transistor 50 can include: fifth source/drain regions 51-52, a fifth channel region between fifth source/drain regions 51-52; and a fifth gate 55 adjacent to the fifth channel region. Fifth source/drain region 51 can be electrically connected to one or more other components of circuit 119. Fifth source/drain region 52 can be electrically connected to third pad 103 (i.e., to the ground pad). Fifth gate 55 can be electrically connected to first pad 101 (e.g., by interconnect 106). Fifth transistor 50 can be an enhancement mode transistor. That is, as discussed above, an enhancement mode transistor is normally in an OFF-state (i.e., a non-conductive state during which current flow through the channel region is blocked) and can be switched to an ON-state (i.e., a conductive state during which current flows through the channel region). Examples of an enhancement mode transistor that can be protected by ESD protection structure 100A, 100B can include, for example, a HEMT modified to include a P-type III-V semiconductor layer (e.g., a P-type gallium nitride layer) in the gate (e.g., as discussed in greater detail below and illustrated in FIG. 3B), a MISHEMT (e.g., as discussed in greater detail below and illustrated in FIG. 3C), an NFET, etc.

FIGS. 3A-3C are cross-section diagrams illustrating examples of a HEMT 300A (i.e., a depletion mode transistor), a modified HEMT 300B that includes a P-type III-V semiconductor layer in the gate (i.e., an enhancement mode transistor), and a MISHEMT 300C (also an enhancement mode transistor), respectively. It should be understood the examples of transistors 300A-300C provided in FIGS. 3A-3C, respectively, and discussed below are provided for illustration purposes and are not intended to be limiting. Various different configurations are known in the art for such transistors and could, alternatively, be included in the disclosed embodiments.

Structures including any of transistors 300A-300C can include substrate 301. Substrate 301 can be, for example, a silicon substrate or a silicon-based substrate (e.g., a silicon carbide or silicon germanium substrate), a sapphire substrate, a III-V semiconductor substrate (e.g., a gallium nitride substrate or other suitable III-V semiconductor substrate) or any other substrate suitable for III-V semiconductor processing. Structures including any of transistors 300A-300C can further include a stack of III-V semiconductor layers on substrate 301. Those skilled in the art will recognize that a III-V semiconductor refers to a compound obtained by combining one or more group III elements, such as boron (B), aluminum (Al), gallium (Ga), or indium (In), with one or more group V elements, such as nitrogen (N), phosphorous (P), arsenic (As) or antimony (Sb)). Thus, examples of III-V semiconductors include, but are not limited to, gallium nitride, indium phosphide, gallium arsenide, aluminum gallium nitride, indium gallium nitride, etc. The III-V semiconductor layers of the stack can be epitaxially grown on substrate 301 and can include a buffer layer 302, a channel layer 303 on the buffer layer 302, and a barrier layer 304 on channel layer 303.

Buffer layer 302 can be above and immediately adjacent to the top surface of substrate 301. Buffer layer 302 can be employed as an anchor to achieve nucleation and to duplicate orientation in subsequently grown epitaxial layers. Buffer layer 302 could be, for example, a gallium nitride layer and/or one or more layers of any other III-V semiconductor(s) suitable for use as a buffer layer for a HEMT or MISHEMT. Optionally, buffer layer 302 can be carbon-doped.

Channel layer 303 can be above and immediately adjacent to the top surface of buffer layer 302. Channel layer 303 could be, for example, a gallium nitride layer and/or one or more layers of any other III-V semiconductor(s) suitable for use as a channel layer of a HEMT or MISHEMT.

Barrier layer 304 can be above and immediately adjacent to channel layer 303. Barrier layer 304 can be yet another III-V semiconductor, which is different from channel layer 303 and which has a band gap that is wider than the bandgap of channel layer 303. Those skilled in the art will recognize that the channel and barrier III-V semiconductor materials can be selected so that a heterojunction is formed at the interface between the two layers, thereby resulting in the formation of a two-dimensional electron gas (2DEG) in channel layer 303. This 2DEG in channel layer 303 can provide the conductive pathway for the drifting of charges between source/drain terminals. Thus, for example, barrier layer 304 could be a layer of aluminum gallium nitride, aluminum nitride or any other III-V semiconductor material suitable for use as a barrier layer (e.g., depending upon the III-V semiconductor material of channel layer 303). In any case, the above-mentioned layers can be epitaxially grown by metal-organic chemical vapor deposition (MOCVD) or any other suitable technique (e.g., molecular beam epitaxy (MBE), hydride vapor phase epitaxy (HVPE), etc.). For purposes of illustration, the figures and the description above depict barrier layer 304 as including a single layer of III-V semiconductor material. However, it should be understood that the figures and description are not intended to be limiting and that, alternatively, barrier layer 304 could include two or more sub-layers of III-V semiconductor materials.

Structures including any of transistors 300A-300C can layers of dielectric material (DM) 350 above barrier layer 304.

Each transistor 300A-300C can include a pair of metallic source/drain terminals 331-332 extending vertically through DM 350 at least partially through barrier layer 304 so as to land on (or be sufficiently close to) channel layer 303 to form ohmic contacts therewith. Metallic source/drain terminals 331-332 can include one or more metal or metal alloy layers suitable for creating such ohmic contacts at metal-semiconductor junctions. Example metal and metal alloy layers that could be employed include, but are not limited to, titanium/aluminum/titanium nitride, titanium/aluminum/titanium/gold, or molybdenum/aluminum/molybdenum/gold.

Each transistor 300A-300C can further include a gate terminal positioned laterally between and electrically isolated from the source/drain terminals. However, the composition of the gate terminal varies depending upon whether the transistor is a depletion mode HEMT 300A, an enhancement mode HEMT 300B, or an enhancement mode MISHEMT 300C.

Specifically, referring to the depletion mode HEMT 300A in FIG. 3A, gate terminal 337a can extend vertically through DM 350 to barrier layer 304 and can include metallic gate conductor material(s) (i.e., metal or metal alloy gate conductor material(s)) above and immediately adjacent to the top surface of barrier layer 304 so that gate terminal 337a is a Schottky contact gate terminal, which will control a two-dimensional electron gas (2DEG) in channel layer 303 thereunder. Example metallic gate conductor materials suitable for creating a Schottky contact gate terminal include, but are not limited to, aluminum, gold, titanium, titanium nitride, nickel/gold, or titanium/platinum/gold.

Referring to the enhancement mode HEMT 300B of FIG. 3B, gate terminal 337b is similar to gate terminal 337a of the above-described depletion mode HEMT 300A, except that it includes a P-type III-V semiconductor layer 336 that is stacked between barrier layer 304 and the metallic gate conductor material(s). P-type III-V semiconductor layer 336 can be, for example, a III-V semiconductor (such as gallium nitride), which is epitaxially grown on barrier layer 304 and which is doped (e.g., with magnesium) so as to have P-type conductivity. In the enhancement mode HEMT 300B, as in the depletion mode HEMT 300A, the metallic gate conductor material(s) can be selected so that they are suitable for creating a Schottky contact gate terminal.

Referring to the enhancement mode MISHEMT 300C of FIG. 3C, gate terminal 337c can extends vertically through DM 350 to barrier layer 304. However, instead of gate conductor material being immediately adjacent to III-V semiconductor material of barrier layer 304, as in depletion mode HEMT 300A, a gate dielectric layer 338 physically separates the gate conductor material from the III-V semiconductor material of the barrier layer 304. Gate dielectric layer 338 can be a dielectric material with a relatively high dielectric constant (K) (e.g., K is greater than the 3.9 dielectric constant of silicon dioxide). This high-K dielectric material could be, for example, aluminum oxide, tantalum oxide, zirconium oxide, a hafnium (Hf)-based dielectric material (e.g., hafnium oxide, hafnium silicon oxide, hafnium silicon oxynitride, hafnium aluminum oxide, etc.) or some other suitable high-K dielectric material. Since gate dielectric layer 338 separates the gate conductor material from barrier layer 304, a Schottky contact gate terminal is not required. Thus, the gate conductor material could include one or more layers of any suitable gate conductor material (e.g., gate metal(s), gate metal alloy(s), doped polysilicon, etc.).

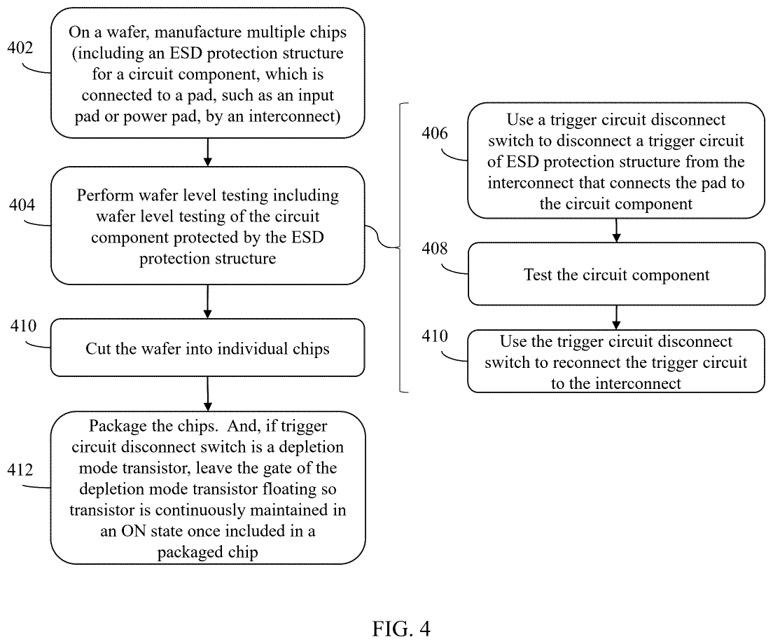

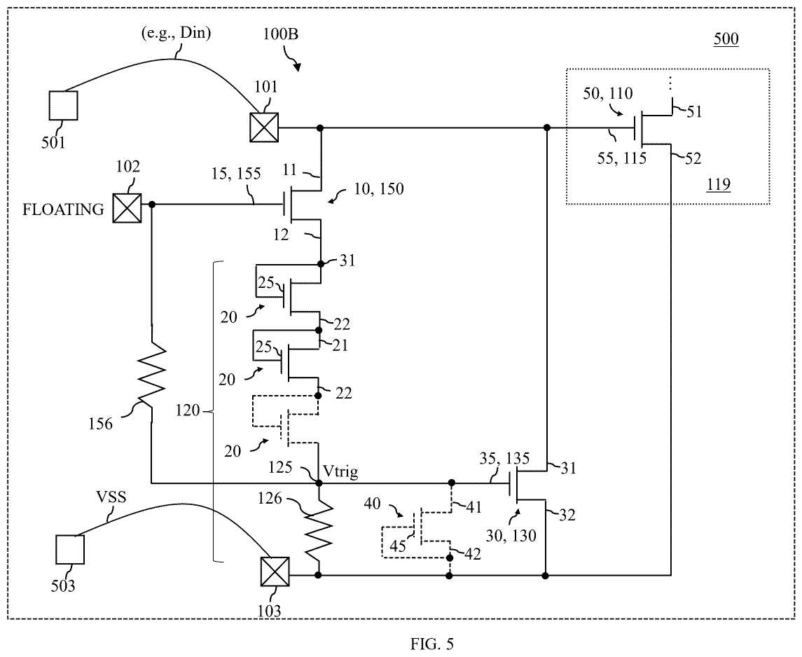

Also disclosed herein are method embodiments associated with the ESD protection structure 100A, 100B including manufacturing, testing, and operating. More specifically, referring to the flow diagram of FIG. 4, the methods can include manufacturing multiple integrated circuit (IC) chips on a wafer (see process 402). The chips can, for example, be manufactured according to a IC design that includes at least one circuit component 110 protected by an ESD protection structure 100A, 100B, as described in detail above and illustrated in FIGS. 1A-1B. Techniques for manufacturing chips on wafers according to IC designs are well known in the art and, thus, the details thereof have been omitted from this specification in order to allow the reader to focus on the salient aspects of the disclosed embodiments.

The methods can further include testing components of the chips on the wafer (referred to herein as wafer level testing) (see process 404). Such wafer level testing can include, but is not limited to, testing the circuit component 110 that is protected by ESD protection structure 100A, 100B. To protect circuit component 110 at process 404, trigger circuit disconnect switch 150 can be used to disconnect trigger circuit 120 from interconnect 106 (which connects circuit component 110 to first pad 101) (see process 406). Circuit component 110 can then be tested (see process 408). Then, trigger circuit disconnect switch 150 can then be used to reconnect trigger circuit 120 to interconnect 106 (see process 410).

More specifically, circuit component testing at process 404 can be performed as follows in embodiments, as described above and illustrated in FIG. 1B, where trigger circuit disconnect switch 150 includes a depletion mode HEMT 10 having a gate 15 electrically connected to a second pad 102 and source/drain regions 11-12 electrically connected to interconnect 106 and to trigger circuit 120. At process 406, a negative voltage can be applied to second pad 102 and, thereby to gate 15 of depletion mode HEMT 10. This negative voltage could, for example, be −20 volts (V) or some other suitable negative voltage for turning off depletion mode HEMT 10 and, thereby opening the switch 150 to electrically disconnect trigger circuit 120 from interconnect 106. At process 408, once trigger circuit 120 is disconnected from trigger circuit 120, wafer level testing of circuit component 110 can be performed. If, as illustrated in FIG. 1B, circuit component 110 is an enhancement mode transistor 50 having a gate 55 electrically connected to a first pad 101 (e.g., an input pad or power pad) by an interconnect 106, the wafer level testing at process 408 can include gate integrity testing. Techniques for gate integrity testing are well known in the art and, thus, specific details thereof have been omitted from this specification in order to allow the reader to focus on the salient aspects of the disclosed embodiments. However, generally, gate integrity testing can include, for example: applying progressively increasing voltages to first pad 101 and thereby to gate 55 via interconnect 106; concurrently measuring current through transistor 50; and comparing measured current values to a maximum leakage current specification to determine whether the transistor 50 passes or fails. By disconnecting trigger circuit 120 from interconnect 106 during such gate integrity testing, the validity of the testing results are not negatively impacted by a confounding variable of leakage current through the trigger circuit 120. At process 410, the negative voltage can be removed from second pad 102 and, thereby from gate 15 of depletion mode HEMT 10. By removing the negative voltage from gate 15, depletion mode HEMT 10 turns back on and switch 150 is closed, thereby reconnecting trigger circuit 120 to interconnect 106 to facilitate ESD protection.

Following wafer level testing, conventional chip manufacturing processes can continue. For example, the wafer can be cut into the individual chips (see process 410) and each chip can be packaged for use in electronic devices (see process 412 and chip package 500 FIG. 5). As illustrated, in chip package 500, first pad 101 can be electrically connected (e.g., through wire bonding or some other suitable technique) to a corresponding pad 501 (e.g., on a printed circuit board (PCB), interposer, etc.) for receiving a signal, as appropriate (e.g., a data input signal (Din) or power signal). Third pad 103 can be connected to a corresponding pad 503 and thereby to ground plane (e.g., on the PCB). In embodiments described above and illustrated in FIG. 1B, where trigger circuit disconnect switch 150 includes a depletion mode HEMT 10 having a gate 15 electrically connected to a second pad 102 and source/drain regions 11-12 electrically connected to interconnect 106 and to trigger circuit 120, second pad 102 can be left floating (i.e., unconnected to any other electrical component), as opposed to connecting it to the PCB, interposer, etc.). By leaving second pad 102 floating, the depletion mode HEMT 10 will remain continuously in an ON state. Thus, within the packaged chip 500, switch 150 is continuously maintained in the closed state so that trigger circuit 120 is electrically connected to interconnect 106 to facilitate ESD protection. Alternatively, if switch 150 is some other type of switch, second pad 102 could be electrically connected to a corresponding pad (e.g., on PCB, interposer, etc.) to receive a control voltage necessary for continuously maintaining the switch in the closed state.

It should be noted that the disclosed ESD protection structure 100B of FIG. 1B can operates to protect circuit component 110 from high positive voltage ESD events (or the like) as well as high negative voltage ESD events (or the like) when switch 150 is closed (i.e., when trigger circuit 120 is electrically connected to interconnect 106 by switch 150). Specifically, during normal operation, trigger circuit 120 will not turn on in response to a received signal below Vmax on first pad 101. Specifically, second transistors 20 will remain turned off and Vtrig will be pulled down toward ground (e.g., at approximately 0.0 volts (V)) through resistor 126. Thus, the enhancement mode transistor 30 of the discharge circuit 130 remains off and essentially the same signal received by first pad 101 is applied to circuit component 110 through interconnect 106.

When a high positive voltage (e.g., to 10V-20V) over Vmax is sensed on first pad 101, trigger circuit 120 will turn on. Specifically, diode-connected enhancement mode second transistors 20 will turn on one after the other and Vtrig at trigger voltage output node 125 will be pulled up (e.g., to 5V-15V). Thus, enhancement mode transistor 30 of discharge circuit 130 turns on and pulls the voltage level on interconnect 106 back down before it is received by circuit component 110. Thus, damage to circuit component 110 is avoided. As mentioned above, in some embodiments, the trigger voltage output node 125 can be electrically connected back to second pad 102. In this case, the positive voltage level of Vtrig can increase drive current of depletion mode transistor 10 of switch 150 and, thereby improve performance.

When a high negative voltage (e.g.,−10V to −20V) is sensed on first pad 101, diode-connected enhancement mode second transistors 20 will be reverse biased so that no current flows therethrough. Additionally, Vtrig at trigger voltage output node 125 will be pulled down toward ground (e.g., at approximately 0.0V). In this case, because the gate voltage of enhancement mode transistor 30 of discharge circuit 130 is positive relative to the negative voltage on interconnect 106, enhancement mode transistor 30 turns on and pulls the voltage level on interconnect 106 back up toward 0.0V. Thus, damage to circuit component 110 is avoided. As mentioned above, in some embodiments, the trigger voltage output node 125 can be electrically connected back to second pad 102. It should be noted that in embodiments including the optional fourth transistor 40, as illustrated in FIG. 1B, this fourth transistor 40 can further operate to improve triggering of enhancement mode transistor 30 during such a high negative voltage ESD event (or the like) by providing a more robust connection to ground than resistor 126 alone.

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a trigger circuit having a trigger voltage output node;
a trigger circuit disconnect switch connected between an interconnect and the trigger circuit, wherein the interconnect connects a first pad to a circuit component; and
a discharge circuit connected to the trigger voltage output node and to the interconnect.

2. The structure of claim 1,
wherein the trigger circuit disconnect switch includes a first transistor, and
wherein the first transistor is a depletion mode transistor including: a first gate connected to a second pad; and first source/drain regions connected to the interconnect and the trigger circuit, respectively.

3. The structure of claim 2,
wherein the trigger circuit includes: a resistor; and multiple second transistors connected in series between the first transistor and the resistor,
wherein the second transistors include diode-connected enhancement mode transistors,
wherein the resistor is connected between the second transistors and a third pad, and
wherein the trigger voltage output node is at a junction between the second transistors and the resistor.

4. The structure of claim 1, further comprising an additional resistor connected between the second pad and the trigger voltage output node.

5. The structure of claim 1,
wherein the discharge circuit includes a third transistor including: a third gate connected to the trigger voltage output node; and third source/drain regions connected to the interconnect and a third pad, respectively, and
wherein the third transistor includes an enhancement mode transistor.

6. The structure of claim 5, further comprising: a fourth transistor including fourth source/drain regions connected to the third gate and the third pad, respectively, wherein the fourth transistor includes a diode-connected enhancement mode transistor.

7. The structure of claim 1, wherein the circuit component includes a fifth transistor including: a fifth gate connected by the interconnect to the first pad.

8. A structure comprising:
an interconnect connected between a first pad and a circuit component; and
an electrostatic discharge protection structure including:
a trigger circuit having a trigger voltage output node;
a trigger circuit disconnect switch connected to a second pad, wherein the trigger circuit disconnect switch and the trigger circuit are further connected between the interconnect and a third pad; and
a discharge circuit connected to the trigger voltage output node and further connected between the interconnect and the third pad.

9. The structure of claim 8, wherein the first pad is connected to receive any of an input signal and a power signal, the second pad is floating, and the third pad is connected to ground.

10. The structure of claim 9,
wherein the trigger circuit disconnect switch includes a first transistor, and
wherein the first transistor is a depletion mode high electron mobility transistor continuously maintained in a conductive state and including: a first gate connected to the second pad; and first source/drain regions connected to the interconnect and the trigger circuit, respectively.

11. The structure of claim 10,
wherein the trigger circuit includes: a resistor; and multiple second transistors connected in series between the first transistor and the resistor,
wherein the second transistors include diode-connected N-type field effect transistors,
wherein the resistor is connected between the second transistors and the third pad, and
wherein the trigger voltage output node is at a junction between the second transistors and the resistor.

12. The structure of claim 8, further comprising an additional resistor connected between the second pad and the trigger voltage output node.

13. The structure of claim 8,
wherein the discharge circuit includes a third transistor including: a third gate connected to the trigger voltage output node; and third source/drain regions connected to the interconnect and the third pad, respectively, and
wherein the third transistor includes an enhancement mode transistor including any of an enhancement mode high electron mobility transistor, an enhancement mode metal-insulator-semiconductor high electron mobility transistor, and an N-type field effect transistor.

14. The structure of claim 13, further comprising a fourth transistor including fourth source/drain regions connected to the third gate and the third pad, respectively, wherein the fourth transistor includes a diode-connected enhancement mode transistor.

15. The structure of claim 8, wherein the circuit component includes a fifth transistor including: a fifth gate connected by the interconnect to the first pad and wherein the fifth transistor include an enhancement mode transistor including any of an enhancement mode high electron mobility transistor, an enhancement mode metal-insulator-semiconductor high electron mobility transistor, and an N-type field effect transistor.

16. A method comprising:
closing a trigger circuit disconnect switch of an electrostatic discharge protection structure for a circuit component on a chip, wherein the circuit component is connected by an interconnect to a first pad and wherein the electrostatic discharge protection structure includes:
a trigger circuit having a trigger voltage output node;
a trigger circuit disconnect switch connected to a second pad, wherein the trigger circuit disconnect switch and the trigger circuit are further connected between the interconnect and a third pad; and
a discharge circuit connected to the trigger voltage output node and further connected between the interconnect and the third pad; and
when the trigger circuit disconnect switch is closed such that the trigger circuit is disconnected from the interconnect, testing the circuit component.

17. The method of claim 16,
wherein the trigger circuit disconnect switch includes a first transistor with a first gate connected to a second pad and first source/drain regions connected to the interconnect and the trigger circuit, respectively,
wherein the first transistor includes a depletion mode transistor, and
wherein the closing of the trigger circuit disconnect switch includes applying a negative voltage to the second pad.

18. The method of claim 17, wherein the method further includes, after the testing, packaging the chip including: connecting the first pad to receive any of an input signal and a power signal, connecting the third pad to ground, and leaving the second pad floating so that, within the packaged chip, the first transistor is continuously maintained in a conductive state.

19. The method of claim 16,
wherein the circuit component includes a transistor having a gate connected to the first pad by the interconnect, and
wherein the testing includes gate integrity testing including: applying progressively increasing voltages to the first pad; measuring current through the transistor during the applying; and comparing current values acquired through the measuring to a maximum leakage current specification.

20. The method of claim 19, wherein the closing of the trigger circuit disconnect switch prevents leakage current through the trigger circuit during the gate integrity testing.
